(19) United States
(12) Patent Application Publication
(10) Pub. No.: US 2024/0315010 A1
(43) Pub. Date: Sep. 19, 2024

(54) SEMICONDUCTOR DEVICES

(71) Applicant: SAMSUNG ELECTRONICS CO., LTD., Suwon-si (KR)

(72) Inventors: Taejin PARK, Suwon-si (KR); Jongmin KIM, Suwon-si (KR); Huijung KIM, Suwon-si (KR); Kiseok LEE, Suwon-si (KR); Myeongdong LEE, Suwon-si (KR)

(21) Appl. No.: 18/435,198

(22) Filed: Feb. 7, 2024

(30) Foreign Application Priority Data
Mar. 17, 2023 (KR) 10-2023-0035239

(51) Int. Cl. H10B 12/00

(52) U.S. Cl. CPC H10B 12/34; H10B 12/03; H10B 12/482; H10B 12/488

(57) ABSTRACT

Provided is a semiconductor device comprising: an active region defined by an element isolation film in a substrate; a word line extending in a first horizontal direction in the substrate; a bit line extending in a second horizontal direction crossing the first horizontal direction on the substrate; an additional pad disposed on the active region; and a buried contact on the additional pad wherein the buried contact is electrically connected to the active region by the additional pad, wherein the additional pad comprises a first surface that overlaps the word line in a vertical direction, and a second surface that is free of overlap with the word line in the vertical direction, and wherein, the first surface meets the second surface at a cusp.

### CROSS-REFERENCE TO RELATED APPLICATION

This application is based on and claims priority under 35 U.S.C. § 119 to Korean Patent Application No. 10-2023-0035239, filed on Mar. 17, 2023, in the Korean Intellectual Property Office, the disclosure of which is incorporated by reference herein in its entirety.

### BACKGROUND

The inventive concept relates to semiconductor devices. Specifically, the inventive concept relates to semiconductor devices including an additional pad.

In accordance with the rapid development of the electronics industry and the needs of users, electronic devices are becoming more compact and lightweight. Accordingly, semiconductor devices having a high degree of integration used in electronic devices are required, and design rules for configurations of semiconductor devices are being reduced.

### SUMMARY

The inventive concept provides semiconductor devices with improved performance and reliability.

The problems to be solved by the inventive concept are not limited to the problems mentioned above, and other problems not mentioned will be clearly understood by those skilled in the art from the description below.

According to an aspect of the inventive concept, there is provided a semiconductor device comprising: an active region defined by an element isolation film in a substrate; a word line extending in a first horizontal direction in the substrate; a bit line extending in a second horizontal direction crossing the first horizontal direction on the substrate; an additional pad disposed on the active region; and a buried contact on the additional pad wherein the buried contact is electrically connected to the active region by the additional pad, wherein the additional pad comprises a first surface that overlaps the word line in a vertical direction, and a second surface that is free of overlap with the word line in the vertical direction, and wherein, the first surface meets the second surface at a cusp.

According to another aspect of the inventive concept, there is provided a semiconductor device comprising: a substrate; a plurality of active regions extending in an oblique direction in the substrate; a plurality of word lines crossing the plurality of active regions in a first horizontal direction and separating each of the plurality of active regions into a first impurity region and a second impurity region; a plurality of bit lines extending in a second horizontal direction crossing the first horizontal direction on the substrate; a plurality of direct contacts electrically connecting the plurality of bit lines to the first impurity regions, respectively; a first trench extending in the first horizontal direction and exposing the second impurity regions of two adjacent active regions among the plurality of active regions; a second trench passing through a lower surface of the first trench in the first trench; a plurality of additional pads between the first trench and the second trench; and a plurality of buried contacts electrically connected to the second impurity regions by the plurality of additional pads, wherein the plurality of direct contacts is arranged in the first horizontal direction, and wherein lower surfaces of the first trench and lower surfaces of the second trench are concave with respect to an upper surface of the substrate.

According to another aspect of the inventive concept, there is provided a semiconductor device comprising: a substrate; a plurality of active regions extending in an oblique direction in the substrate and spaced apart from each other in a first horizontal direction; a plurality of word lines crossing the plurality of active regions in the first horizontal direction and separating each of the plurality of active regions into a first impurity region and second impurity regions spaced apart from each other with the first impurity region therebetween; a plurality of bit lines extending in a second horizontal direction crossing the first horizontal direction on the substrate and electrically connected to the first impurity regions by a plurality of direct contacts, respectively; a first trench extending in the first horizontal direction and exposing the second impurity regions of two adjacent active regions among the plurality of active regions; a second trench extending in the first horizontal direction, having a width equal to or narrower than that of the first trench in the second horizontal direction at a same vertical level, relative to the substrate, and passing through a lower surface of the first trench; a plurality of additional pads disposed inside the first trench and outside the second trench, the plurality of additional pads, respectively including a first polysilicon layer; and a plurality of buried contacts electrically connected to the second impurity regions by the plurality of additional pads, respectively, wherein each of the plurality of additional pads comprises a first surface that overlaps one of the plurality of word lines in a vertical direction, and a second surface that is free of overlap with the plurality of word lines in the vertical direction, and wherein the first surface meets the second surface at a cusp.

### BRIEF DESCRIPTION OF THE DRAWINGS

Embodiments will be more clearly understood from the following detailed description taken in conjunction with the accompanying drawings in which:

FIG. 1A is a schematic layout diagram of a semiconductor device according to example embodiments;

FIG. 1B is a layout diagram illustrating some components of a semiconductor device according to example embodiments;

FIGS. 2A and 2B are cross-sectional views taken along lines A-A′ and B-B′ of FIG. 1A, respectively;

FIG. 3 is an enlarged cross-sectional view of region EX1 of FIG. 2A;

FIGS. 4A to 4D are enlarged cross-sectional views illustrating some components of a semiconductor device according to example embodiments;

FIG. 5 is a cross-sectional view showing some components of a semiconductor device according to example embodiments;

FIGS. 6 and 7 are cross-sectional views illustrating some components of a semiconductor device according to example embodiments;

FIGS. 8A, 8B, 9A, 9B, 10A, 10B, 11A, 11B, 12A, 12B, 13A, 13B, 13C, 14A, 14B, 15A, 15B, and 15C are diagrams for explaining a method of manufacturing a semiconductor device, according to example embodiments; and

FIGS. 16A and 16B are cross-sectional views illustrating a method of manufacturing a semiconductor device, according to example embodiments.

### DETAILED DESCRIPTION

Hereinafter, embodiments of the inventive concept will be described in detail with reference to the accompanying drawings.

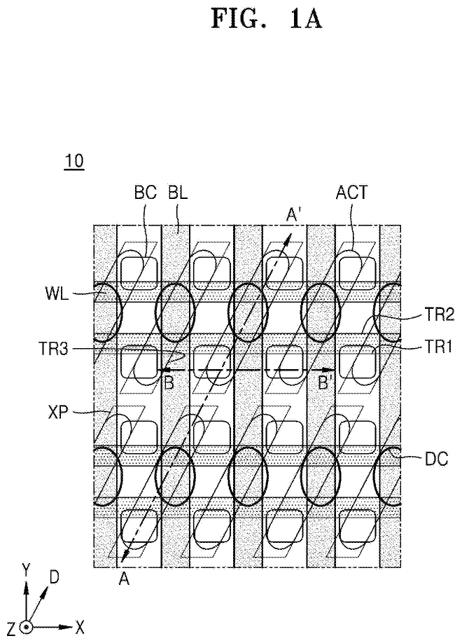

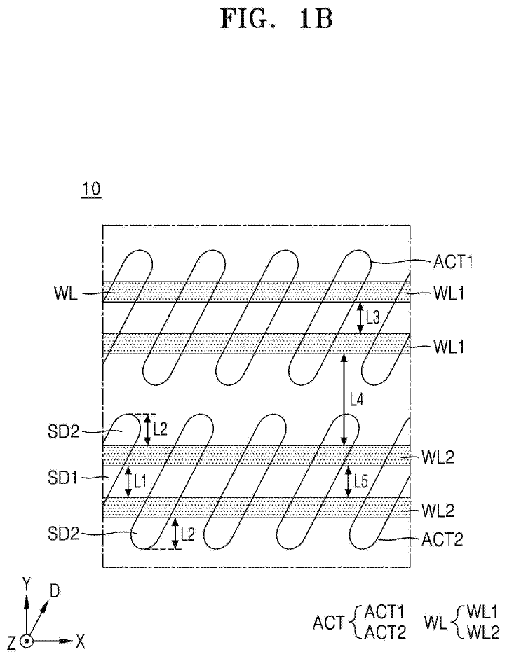

FIG. 1A is a schematic layout diagram of a semiconductor device 10 according to example embodiments.

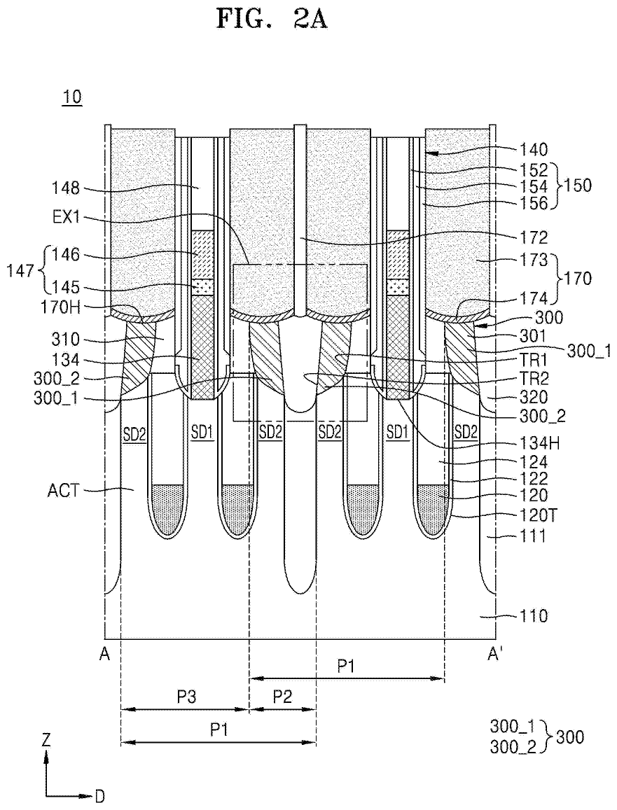

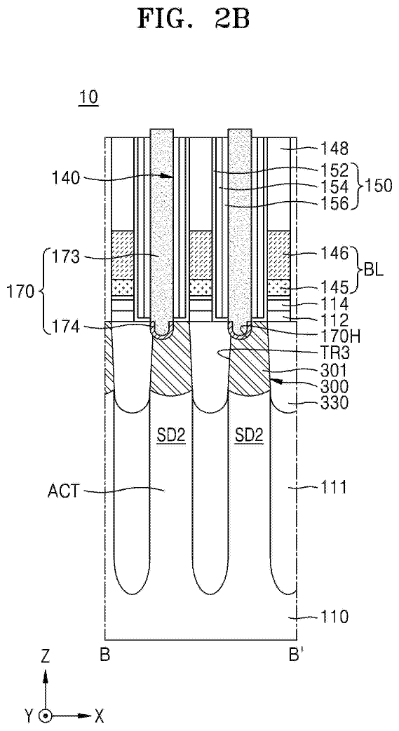

Referring to FIG. 1A, the semiconductor device 10 may include a plurality of active regions ACT disposed to extend in an oblique direction (e.g., D direction) with respect to a first horizontal direction (e.g., X direction) and a second horizontal direction (e.g., Y direction) on a plane. The first and second horizontal directions may be parallel with an upper surface of a substrate (referring to the substrate 110 in FIG. 2A). The first horizontal direction may intersect with (e.g., may be perpendicular to) the second horizontal direction. In example embodiments, the plurality of active regions ACT may be arranged in a line in the first horizontal direction (e.g., X direction). For example, long axes of the plurality of active regions ACT may extend in the oblique direction (e.g., D direction) and may be arranged in the line in the first horizontal direction (e.g., X direction). That is, the long axes of each of the plurality of active regions ACT may overlap each other in parallel in the first horizontal direction (e.g., X direction). In example embodiments, the plurality of active regions ACT may be arranged in a line in the oblique direction (e.g., D direction).

In some embodiments, a plurality of word lines WL may extend parallel to each other in the first horizontal direction (e.g., X direction) across the plurality of active regions ACT. A plurality of bit lines BL may extend parallel to each other in the second horizontal direction (e.g., Y direction) crossing the first horizontal direction (e.g., X direction) on the plurality of word lines WL.

The plurality of bit lines BL may be connected (e.g., electrically connected) to the plurality of active regions ACT through a plurality of direct contacts DC. In some embodiments, the plurality of direct contacts DC may be arranged in a line in the first horizontal direction (e.g., X direction) and a line in the second horizontal direction (e.g., Y direction). That is, the plurality of direct contacts DC may overlap each other in the first horizontal direction (e.g., X direction) and the second horizontal direction (e.g., Y direction).

In some embodiments, a plurality of buried contacts BC may be formed between two mutually adjacent bit lines BL among the plurality of bit lines BL. In some embodiments, the plurality of buried contacts BC may be arranged in a line in the first horizontal direction (e.g., X direction) and a line in the second horizontal direction (e.g., Y direction). The plurality of buried contacts BC may be connected (e.g., electrically connected) to the plurality of active regions ACT through a plurality of additional pads XP. The sizes and shapes of the plurality of buried contacts BC are not limited to those shown.

In some embodiments, the plurality of additional pads XP may be planarly disposed on the edge of each of the plurality of active regions ACT to electrically connect the plurality of buried contacts BC to the plurality of active regions ACT. In some embodiments, the plurality of additional pads XP may be arranged in a line in the first horizontal direction (e.g., X direction) and in a line in the oblique direction (e.g., D direction). The size and shape of the plurality of additional pads XP are not limited to those shown.

The semiconductor device 10 may be a dynamic random access memory (DRAM) device, but is not limited thereto.

FIG. 1B is a layout diagram illustrating some components of the semiconductor device 10 according to example embodiments.

Referring to FIG. 1B, the plurality of word lines WL may extend crossing the plurality of active regions ACT in the first horizontal direction (e.g., X direction). An active region ACT among the plurality of active regions ACT may include a first impurity region SD1 and second impurity regions SD2 that are spaced apart from each other with the first impurity region SD1 therebetween. For example, a word line WL among the plurality of word lines WL may separate the active region ACT into the first impurity region SD1 and the second impurity region SD2. The first impurity region SD1 and the second impurity region SD2 may be spaced apart with the word line WL therebetween.

In some embodiments, the plurality of active regions ACT may be divided into thirds by the plurality of word lines WL. For example, an active region ACT among the plurality of active regions ACT may be divided into thirds by two word lines WL among the plurality of word lines WL. Specifically, the first impurity region SD1 and the second impurity region SD2 separated by the word lines WL (e.g., two word lines WL) may have the same length. For example, the length L1 of the first impurity region SD1 in the second horizontal direction (e.g., Y direction) may be equal to the length L2 of the second impurity region SD2 in the second horizontal direction (e.g., Y direction).

In some embodiments, the plurality of active regions ACT may include a plurality of first active regions ACT1 overlapping each other in the first horizontal direction (e.g., X direction), and a plurality of second active regions ACT2 spaced apart from the plurality of first active regions ACT1 in the second horizontal direction (e.g., Y direction) and overlapping each other in the first horizontal direction (e.g., X direction).

In some embodiments, the plurality of word lines WL may include a plurality of first word line WL1 overlapping the plurality of first active regions ACT1 and a plurality of second word line WL2 overlapping the plurality of second active regions ACT2. For example, the plurality of word lines WL may include two first word lines WL1 overlapping the plurality of first active regions ACT1 and two second word lines WL2 overlapping with the plurality of second active regions ACT2. The two first word lines WL1 may be spaced apart from each other in the second horizontal direction (e.g., Y direction). The two second word lines WL2 may be spaced apart from each other in the second horizontal direction (e.g., Y direction).

In some embodiments, a distance L3 in the second horizontal direction (e.g., Y direction) between the two first word lines WL1 may be equal to a distance L5 in the second horizontal direction (e.g., Y direction) between the two second word lines WL2. That is, two word lines WL crossing one active region ACT may be arranged at equal intervals.

On the other hand, a distance L4 in the second horizontal direction (e.g., Y direction) between the first word line WL1 and the adjacent second word line WL2 may be different from the distance L3 between the two first word lines WL1. Specifically, the distance L4 between the first word line WL1 and the adjacent second word line WL2 may be greater than the distance L3 between the two first word lines WL1. For example, the distance L4 between the first word line WL1 and the adjacent second word line WL2 may be greater than twice the distance L3 between the two first word lines WL1. That is, the plurality of word lines WL may not be equally spaced. In particular, the distance between the plurality of word lines WL crossing different active regions ACT may not be equal to the distance between the word lines WL crossing one active region ACT.

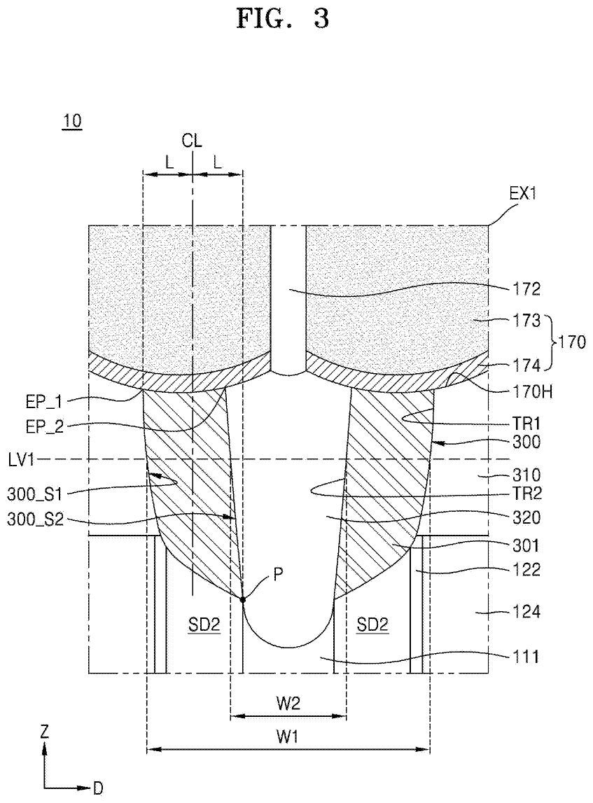

FIGS. 2A and 2B are cross-sectional views taken along lines A-A′ and B-B′ of FIG. 1A, respectively. FIG. 3 is an enlarged cross-sectional view of region EX1 of FIG. 2A. Specifically, FIG. 3 is an enlarged cross-sectional view of the region EX1 including an additional pad 300 for explaining the additional pad 300 in detail.

Referring to FIGS. 2A and 2B, the semiconductor device 10 may include a substrate 110 in which the plurality of active regions ACT are defined by an element isolation film 111.

The substrate 110 may be a wafer including silicon (Si). In some embodiments, the substrate 110 may be a wafer including a semiconductor element, such as germanium (Ge), or a compound semiconductor, such as silicon carbide (SiC), gallium arsenide (GaAs), indium arsenide (InAs), and/or indium phosphide (InP). In some embodiments, the substrate 110 may have a silicon on insulator (SOI) structure. In some embodiments, the substrate 110 may include a conductive region, for example, a well doped with an impurity and/or a structure doped with an impurity.

In some embodiments, the element isolation film 111 may include a first element isolation film, a second element isolation film, and a third element isolation film, but is not limited thereto. For example, the first element isolation film may be conformally disposed on (e.g., conformally cover) inner side and inner lower surfaces of an element isolation trench. In some embodiments, the first element isolation film may include silicon oxide. For example, the second element isolation film may be conformally disposed on (e.g., cover) the first element isolation film. In some embodiments, the second element isolation film may include silicon nitride. For example, the third element isolation film may be disposed on (e.g., cover) the second element isolation film and may fill the element isolation trench. In some embodiments, the third element isolation film may include silicon oxide. For example, the third element isolation film may include silicon oxide formed of tonen silazene (TOSZ). In some embodiments, the element isolation film 111 may include a single layer, including one kind of insulating film, a double layer, including two kinds of insulating films, or a multi-layer, including a combination of at least four kinds of insulating films. For example, the element isolation film 111 may include a single film, including silicon oxide.

A plurality of word line trenches 120T may be formed in the substrate 110 that includes the plurality of active regions ACT defined by the element isolation film 111. The plurality of word line trenches 120T may extend parallel to each other in the first horizontal direction (e.g., X direction), and each may have a line shape that crosses the active region ACT and is disposed (e.g., arranged) in the second horizontal direction (e.g., Y direction). In some embodiments, step profiles in a cross-sectional view may be formed on lower surfaces of the plurality of word line trenches 120T.

A plurality of gate dielectric films 122, a plurality of word lines 120, and a plurality of dummy buried insulating films 124 may be sequentially formed inside the plurality of word line trenches 120T. The plurality of word lines 120 may respectively comprise the plurality of word lines WL illustrated in FIGS. 1A and 1B. The plurality of word lines 120 may extend parallel to each other in the first horizontal direction (e.g., X direction), and each may have a line shape that crosses the active region ACT and is disposed (e.g., arranged) in the second horizontal direction (e.g., Y direction). An upper surface of each of the plurality of word lines 120 may be at a vertical level that is lower than an upper surface of the substrate 110. The vertical level may be a relative location (e.g., distance) from a lower surface of the substrate 110 in a vertical direction (e.g., Z direction). A farther distance from the lower surface of the substrate 110 may be a higher vertical level. A closer distance from the lower surface of the substrate 100 may be a lower vertical level. The vertical direction (e.g., Z direction) may be perpendicular to the upper surface of the substrate 110. The vertical direction (e.g., Z direction) may be perpendicular to the first and second directions (e.g., X direction and Y direction).

The plurality of word lines 120 may respectively fill lower portions of the plurality of word line trenches 120T. Each of the plurality of word lines 120 may have a stacked structure of a lower word line layer (not shown) and an upper word line layer (not shown). For example, the lower word line layer may have the gate dielectric film 122 therebetween and conformally cover inner walls and a lower portion of the lower portion of the word line trench 120T. For example, an upper word line layer may cover the lower word line layer, have a gate dielectric film 122 therebetween, and fill the lower portion of the word line trench 120T. In some embodiments, the lower word line layer may include, for example, a metal material, such as Ti, TiN, Ta, or TaN, and/or a conductive metal nitride. In some embodiments, the upper word line layer may include, for example, doped polysilicon, a metal material, such as W, a conductive metal nitride, such as WN, TiSiN, or WSiN, and/or a combination thereof.

A source region and a drain region formed by implanting impurity ions in a portion of the active region ACT may be disposed in the substrate 110 on both sides of each of the plurality of word lines 120. For example, the first impurity region SD1 and the second impurity region SD2 may function as a source region and a drain region, respectively. For example, the first impurity region SD1 may be a source region, and the second impurity region SD2 may be a drain region, or vice versa.

The gate dielectric film 122 may be on (e.g., may cover) inner walls and lower surfaces of the word line trench 120T. In some embodiments, the gate dielectric film 122 may extend from between the word line 120 and the word line trench 120T to between a dummy buried insulating film 124 and the word line trench 120T. The dummy buried insulating film 124 may be on the word line 120. For example, a lower surface of the dummy buried insulating film 124 may be on an upper surface of the word line 120. The gate dielectric film 122 may include, for example, silicon oxide, silicon nitride, silicon oxynitride, oxide/nitride/oxide (ONO), and/or a high-k dielectric material having a higher dielectric constant than silicon oxide. For example, the high-k dielectric film may have a dielectric constant of about 10 to about 25. In some embodiments, the gate dielectric film 122 may include, for example, Hafnium Oxide (HfO), Hafnium Silicate (HfSiO), Hafnium Oxide Nitride (HfON), Hafnium Silicon Oxide Nitride (HfSiON), Lanthanum Oxide (LaO), Lanthanum Aluminum Oxide (LaAIO), Zirconium Oxide (ZrO), Zirconium Silicate (ZrSiO), Zirconium Oxynitride (ZrON), Zirconium Silicon Oxynitride (ZrSiON), Tantalum Oxide (TaO), Titanium Oxide (TiO), Barium Strontium Titanium Oxide (BaSrTiO), Barium Titanium Xxide (BaTiO), Strontium Titanium Oxide (SrTiO), Yttrium Oxide (YO), Aluminum Oxide (AlO), and/or Lead Scandium Tantalum Oxide (PbScTaO). For example, the gate dielectric film 122 may include HfO2, Al2O3, HfAlO3, Ta2O3, or TiO2.

The plurality of dummy buried insulating films 124 may fill upper portions of the plurality of word line trenches 120T. In some embodiments, upper surfaces of the plurality of dummy buried insulating films 124 may be at the same or substantially the same vertical level as the upper surface of the substrate 110. The dummy buried insulating film 124 may include, for example, silicon oxide, silicon nitride, silicon oxynitride, and/or a combination thereof. For example, the dummy buried insulating film 124 may include silicon nitride.

Insulating film patterns 112 and 114 may be disposed on the element isolation film 111, the plurality of active regions ACT, and the plurality of dummy buried insulating films 124. In some embodiments, the insulating film patterns 112 and 114 may have a stacked structure of a plurality of insulating films including a first insulating film pattern 112 and a second insulating film pattern 114. In some embodiments, the first insulating film pattern 112 may include, for example, silicon oxide, and the second insulating film pattern 114 may include, for example, silicon oxynitride. In some embodiments, the first insulating film pattern 112 may include, for example, a non-metal-based dielectric material, and the second insulating film pattern 114 may include, for example, a metal-based dielectric material.

A plurality of direct contact conductive patterns 134 may respectively fill a portion of a plurality of direct contact holes 134H exposing the source region (e.g., the first impurity region SD1) in the active region ACT. In some embodiments, the direct contact hole 134H may extend into the active region ACT, that is, into the source region. For example, the direct contact hole 134H may expose the first impurity region SD1 and extend into the first impurity region SD1. Specifically, the plurality of direct contact conductive patterns 134 may be electrically connected to the first impurity regions SD1, respectively. In some embodiments, the plurality of direct contact conductive patterns 134 may include, for example, doped polysilicon. For example, the plurality of direct contact conductive patterns 134 may include an epitaxial silicon layer. The plurality of direct contact conductive patterns 134 may configure the plurality of direct contacts DC illustrated in FIG. 1A. As used herein, “an element A exposing an element B” means that at least one portion of the element B is free of contact with the element A. Another portion of the element B may be in contact with the element A. The element B may be in contact with other elements than the element A.

A plurality of bit line structures 140 may be disposed on the insulating film patterns 112 and 114. Each of the plurality of bit line structures 140 may include a bit line 147 and an insulating capping line 148 on (e.g., covering) the bit line 147. The plurality of bit line structures 140 may extend parallel to each other in the second horizontal direction (e.g., Y direction). The plurality of bit lines 147 may respectively comprise the plurality of bit lines BL illustrated in FIG. 1A. The plurality of bit lines 147 may be electrically connected to the plurality of active regions ACT through the plurality of direct contact conductive patterns 134. In detail, the plurality of bit lines 147 may be electrically connected to the first impurity region SD1 through the plurality of direct contact conductive patterns 134. In some embodiments, the plurality of insulating capping lines 148 may include silicon nitride, but is not limited thereto.

The bit line 147 may have a stacked structure of a line-shaped first metal-based conductive pattern 145 and a second metal-based conductive pattern 146. In some embodiments, the first metal-based conductive pattern 145 may include, for example, titanium nitride (TiN) and/or Ti—Si—N (TSN), and the second metal-based conductive pattern 146 may include, for example, tungsten (W) and/or tungsten silicide (WSix). In some embodiments, the first metal-based conductive pattern 145 may function as a diffusion barrier.

A plurality of insulating spacer structures 150 may be disposed on (e.g., may cover) both sidewalls of the plurality of bit line structures 140. Each of the plurality of insulating spacer structures 150 may include a first insulating spacer 152, a second insulating spacer 154, and a third insulating spacer 156. In some embodiments, the plurality of insulating spacer structures 150 may extend into the plurality of direct contact holes 134H and may be disposed on (e.g., may cover) both sidewalls of the plurality of direct contact conductive patterns 134. The first, second, and third insulating spacers 152, 154, and 156 may be sequentially formed on both sidewalls of the plurality of direct contact conductive patterns 134. For example, the first insulating spacer 152 may be in contact with the sidewalls of the plurality of direct contact conductive patterns 134, and the second insulating spacer 154 may be between the first insulating spacer 152 and the third insulating spacer 156. The second insulating spacer 154 may include a material having a lower permittivity than the first insulating spacer 152 and the third insulating spacer 156. In some embodiments, the first insulating spacer 152 and the third insulating spacer 156 may include, for example, nitride, and the second insulating spacer 154 may include, for example, oxide. In some embodiments, the first insulating spacer 152 and the third insulating spacer 156 may include, for example, nitride, and the second insulating spacer 154 may include a material having an etch selectivity with respect to the first insulating spacer 152 and the third insulating spacer 156. For example, the first insulating spacer 152 and the third insulating spacer 156 may include nitride, and the second insulating spacer 154 may be an air spacer. In some embodiments, the insulating spacer structure 150 may include a second insulating spacer 154, including oxide and a third insulating spacer 156, including nitride.

A plurality of buried contacts 170 may be disposed in a plurality of buried contact holes 170H between each of the plurality of bit lines 147. The plurality of buried contacts 170 may be disposed between a pair of insulating spacer structures 150 facing each other among the plurality of insulating spacer structures 150 covering both sidewalls of the plurality of bit line structures 140. For example, one buried contact 170 may be disposed between the pair of insulating spacer structures 150 in the first horizontal direction (e.g., X direction). For example, a pair of buried contacts 170 may be disposed between a pair of insulating spacer structures 150 in the oblique direction (e.g., D direction). The pair of insulating spacer structures 150 in the oblique may include two insulating spacer structures 150 on sidewalls of two different bit line structures 140.

In some embodiments, the plurality of buried contacts 170 may include a first silicide film 174 disposed in the plurality of buried contact holes 170H and a first metal conductive layer 173 disposed on the first silicide film 174, respectively. The first silicide film 174 may be disposed between the first metal conductive layer 173 and a first polysilicon layer 301. The first metal conductive layer 173 may be spaced apart from the first polysilicon layer 301 with the first silicide film 174 therebetween. The first polysilicon layer 301 may be disposed on the second impurity region SD2. The first polysilicon layer 301 may be disposed between the first silicide film 174 and the second impurity region SD2.

In some embodiments, the first silicide film 174 may include a metal silicide. For example, the first silicide film 174 may include Ti, W, Ru, Nb, Mo, Hf, Ni, Co, Pt, Yb, Tb, Dy, Er, and/or Pd. For example, the first silicide film 174 may include titanium silicide but is not limited thereto.

In some embodiments, the plurality of buried contacts 170 may be arranged in a line in each of the first horizontal direction (e.g., X direction) and the second horizontal direction (e.g., Y direction). Each of the plurality of buried contacts 170 may extend from the active region ACT in the vertical direction (e.g., Z direction). In detail, each of the plurality of buried contacts 170 may extend from the second impurity region SD2 in the vertical direction (e.g., Z direction). The plurality of buried contacts 170 may comprise the plurality of buried contacts BC illustrated in FIG. 1A. In some embodiments, the plurality of buried contacts 170 may be electrically connected to the plurality of active regions ACT through additional pads 300 to be described below. In detail, the plurality of buried contacts 170 may be electrically connected to the second impurity region SD2 through an additional pad 300 to be described below.

A vertical level of upper surfaces of the plurality of buried contacts 170 may be higher than a vertical level of upper surfaces of the plurality of insulating capping lines 148. Unlike shown, the vertical level of the upper surfaces of the plurality of buried contacts 170 may be equal to or lower than the vertical level of the upper surfaces of the plurality of insulating capping lines 148.

In some embodiments, a partition 172 may be disposed between the pair of buried contacts 170 disposed between the pair of insulating spacer structures 150 in the oblique direction (e.g., D direction). Specifically, the pair of buried contacts 170 disposed in the oblique direction (e.g., D direction) may be spaced apart from each other in the oblique direction (e.g., D direction) with the partition 172 therebetween. That is, a buried contact among the plurality of buried contacts 170 may be disposed between the insulation spacer structure 150 and the partition 172 in the oblique direction (e.g., D direction). The partition 172 may include an insulating material. For example, the partition 172 may include, for example, silicon nitride, silicon oxide, and/or silicon oxynitride.

In some embodiments, an additional pad 300 may be disposed on the second impurity region SD2. The additional pad 300 may mediate an electrical connection between the buried contact 170 disposed on the additional pad 300 and the second impurity region SD2. That is, the buried contact 170 may be electrically connected to the second impurity region SD2 through the additional pad 300. Each of the plurality of additional pads 300 may be disposed to overlap each of the plurality of second impurity regions SD2 in the vertical direction (e.g., Z direction). The plurality of additional pads 300 may respectively comprise the plurality of additional pads XP illustrated in FIG. 1A. For example, the additional pad 300 may include the first polysilicon layer 301.

In some embodiments, the plurality of additional pads 300 may overlap each other and may be disposed between a first trench TR1 and a second trench TR2 extending in the first horizontal direction (e.g., X direction), respectively (see FIG. 1A). In some embodiments, the plurality of additional pads 300 may be disposed in the third trench TR3 extending in the oblique direction (e.g., D direction). Details will be described below with reference to FIGS. 3 and 8A to 15C.

In some embodiments, the pair of buried contacts 170 disposed between the pair of insulating spacer structures 150 in the oblique direction (D direction) may be connected (e.g., electrically connected) to different active regions ACT through a pair of additional pads 300. Specifically, the pair of buried contacts 170 disposed between the pair of insulating spacer structures 150 in the oblique direction (e.g., D direction) may be connected (e.g., electrically connected) to the second impurity region SD2 of each of the different active regions ACT through the pair of additional pads 300. The pair of second impurity regions SD2 connected (e.g., electrically connected) to the pair of buried contacts 170 disposed between the pair of insulating spacer structures 150 in the oblique direction (e.g., D direction) may be adjacent to each other among the second impurity regions SD2 of each different active region ACT.

In some embodiments, the plurality of additional pads 300 may include a first additional pad 300_1 and a second additional pad 300_2. The first additional pad 300_1 may be arranged at a first interval P1 in the oblique direction (e.g., D direction) with the adjacent first additional pad 300_1. The second additional pads 300_2 may be arranged at a first interval P1 in the oblique direction (e.g., D direction) with the adjacent second additional pads 300_2. In some embodiments, the first additional pad 300_1 may be arranged with the adjacent second additional pad 300_2 at a second interval P2 or a third interval P3. Specifically, the first additional pad 300_1 and the adjacent second additional pad 300_2 disposed together in the first trench TR1 may be arranged at a second interval P2 in the oblique direction (e.g., D direction). That is, the first additional pad 300_1 and the second additional pad 300_2 disposed on different active regions ACT and adjacent to each other may be arranged at a second interval P2 in the oblique direction (e.g., D direction). Specifically, the first additional pad 300_1 and the adjacent second additional pad 300_2 disposed in the first trench TR1 may be arranged at a third interval P3 in the oblique direction (e.g., D direction). That is, the first additional pad 300_1 and the second additional pad 300_2 disposed on different active regions ACT and adjacent to each other may be arranged at the third interval P3 in the oblique direction (e.g., D direction).

Hereinafter, the additional pad 300 will be described in detail with reference to FIG. 3.

Referring to FIG. 3, the plurality of additional pads 300 may be disposed in the first trench TR1 penetrating the interlayer insulating film 310. Specifically, the plurality of additional pads 300 may be disposed between the first trench TR1 penetrating the interlayer insulating film 310 and the second trench TR2 penetrating the lower surface of the first trench TR1. That is, the plurality of additional pads 300 may be disposed within the first trench TR1 and outside the second trench TR2.

In some embodiments, the first trench TR1 may extend in the first horizontal direction (e.g., X direction). In some embodiments, the second trench TR2 may extend in the first horizontal direction (e.g., X direction). The first trench TR1 and the second trench TR2 may overlap each other. For example, the second trench TR2 may be narrower in width and deeper than the first trench TR1 and may be disposed to penetrate the lower surface of the first trench TR1. In this specification, a width of the first trench TR1 and a width of the second trench TR2 may be compared at the same vertical level. For example, a width W1 of the first trench TR1 at a vertical level LV1 may be at least equal to or greater than a width W2 of the second trench TR2 at the same vertical level. In this specification, comparison of the depth of the first trench TR1 and the depth of the second trench TR2 may be performed by comparing vertical levels of the lowest point of the lower surface of the first trench TR1 to the lowest point of the lower surface of the second trench TR2. In some embodiments, since the second trench TR2 is disposed penetrating the lower surface of the first trench TR1, the lowermost point of the lower surface of the second trench TR2 may have a vertical level that is lower than that of the lowermost point of the lower surface of the first trench TR1.

In some embodiments, a pair of additional pads 300 disposed between the first trench TR1 and the second trench TR2 may be separated by an inter-pad insulating film 320 disposed in the second trench TR2. In some embodiments, the pair of additional pads 300 disposed between the first trench TR1 and the second trench TR2 may have a shape that extends around (e.g., surrounds) a portion of the inter-pad insulating film 320 from the outside of the second trench TR2 (e.g., outside of the inter-pad insulating film 320). In some embodiments, the partition 172 disposed between the pair of buried contacts 170 may be disposed recessing an upper portion of the inter-pad insulating film 320. Similarly, the buried contact 170 disposed in the buried contact hole 170H may be disposed recessing an upper portion of the additional pad 300.

In some embodiments, the additional pad 300 may include a first surface 300_S1 and a second surface 300_S2. The first surface 300_S1 of the additional pad 300 may overlap the word line 120 (see FIG. 2A) in the vertical direction (e.g., Z direction). The second surface 300_S2 of the additional pad 300 may not overlap the word line 120 in the vertical direction (e.g., Z direction). The first surface 300_S1 of the additional pad 300 may be disposed on an inner wall of the first trench TR1, and the second surface 300_S2 of the additional pad 300 may be disposed on an outer wall of the second trench TR2. In some embodiments, the first surface 300_S1 and the second surface 300_S2 of the additional pad 300 may be concave with respect to the inter-pad insulating film 320, but are not limited thereto.

In some embodiments, the first surface 300_S1 of each of the pair of additional pads 300 disposed in one first trench TR1 may be spaced apart from each other with the second surface 300_S2 of each of the pair of additional pads 300 therebetween. In some embodiments, the second surfaces 300_S2 of each of the pair of additional pads 300 disposed in one first trench TR1 may be spaced apart from each other with the inter-pad insulating film 320 therebetween.

In some embodiments, a pair of additional pads 300 disposed in one first trench TR1 may have a mirror symmetrical structure with respect to each other. For example, the pair of additional pads 300 disposed in one first trench TR1 may have a mirror symmetrical structure with respect to the inter-pad insulating film 320 disposed therebetween. That is, the first surfaces 300_S1 of each of the pair of additional pads 300 disposed in one first trench TR1 may have a mirror symmetrical structure with respect to each other. That is, the second surfaces 300_S2 of each of the pair of additional pads 300 disposed in one first trench TR1 may have a mirror symmetrical structure with respect to each other.

In some embodiments, the first surface 300_S1 and the second surface 300_S2 may meet at a cusp P in terms of a cross-sectional area passing in the oblique direction (e.g., D direction). The cusp P may refer to a location where the first surface 300_S1 and the second surface 300_S2 meet each other because of the difference between the slope of the first surface 300_S1 and the slope of the second surface 300_S2. The cusp P may be, for example, a line. Specifically, in terms of cross-sectional area, the first surface 300_S1 and/or the second surface 300_S2 may include a portion where the slope changes and may meet each other at the cusp P. The cusp P may not overlap the upper surface of the additional pad 300 in the vertical direction (e.g., Z direction). The cusp P may not overlap the word line 120 in the vertical direction (e.g., Z direction). The cusp P may be positioned on a line where the first trench TR1 intersects with the second trench TR2. The cusp P may be one end of the first surface 300_S1 and one end of the second surface 300_S2 at the same time. The cusp P may be located closer to the other end EP_2 of the second face 300_S2 than to the other end EP_1 of the first face 300_S1. In the illustrated embodiment, the cusp P may be disposed on the second impurity region SD2 but is not limited thereto. For example, unlike shown, the cusp P may not be disposed on the second impurity region SD2 but may be disposed on the element isolation film 111 between two adjacent second impurity regions SD2. In other words, the cusp P may overlap the second impurity region SD2 in the vertical direction (e.g., Z direction) or unlike shown, may not overlap the second impurity region SD2 in the vertical direction (e.g., Z direction). As used herein, “an element A overlapping an element B in a direction X” (or similar language) means that there is at least one line that extends in the direction X and intersects both the elements A and B.

In some embodiments, a width of the buried contact 170 in the oblique direction (e.g., D direction) may be greater than a width of the additional pad 300 in the oblique direction (e.g., D direction). For example, the buried contact 170 may overlap both the first and second surfaces 300_S1 and 300_S2 of the additional pad 300 in the vertical direction (e.g., Z direction). Unlike shown, the buried contact 170 may not overlap the first surface 300_S1 or the second surface 300_S2 of the additional pad 300 in the vertical direction (e.g., Z direction).

In some embodiments, a cross-section of the additional pad 300 may be asymmetrical with respect to the center line CL of the additional pad 300. The center line CL of the additional pad 300 may refer to a line extending the same distance to both ends (e.g., opposing ends) of the additional pad 300. In the illustrated embodiment, the both ends of the additional pad 300 may include both ends (e.g., opposing ends) of the first surface 300_S1, respectively. For example, the both ends of the additional pad 300 may include a cusp P and the other end EP_1 of the first surface 300_S1. For example, distances from the center line CL of the additional pad 300 to the both ends of the additional pad 300, that is, the cusp P and the other end EP_1 of the first surface 300_S1 in the oblique direction (e.g., D direction), may refer to lines having the same distance as L, respectively.

In some embodiments, the first trench TR1 in which the additional pad 300 is disposed may expose the gate dielectric film 122 while exposing the second impurity region SD2. That is, the additional pad 300 disposed in the first trench TR1 may be connected to the second impurity region SD2 and may also contact the gate dielectric film 122.

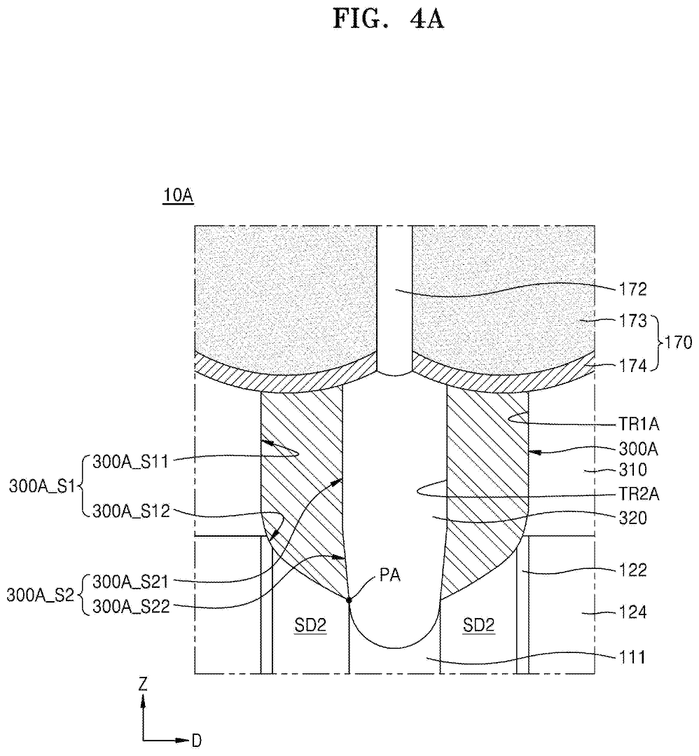

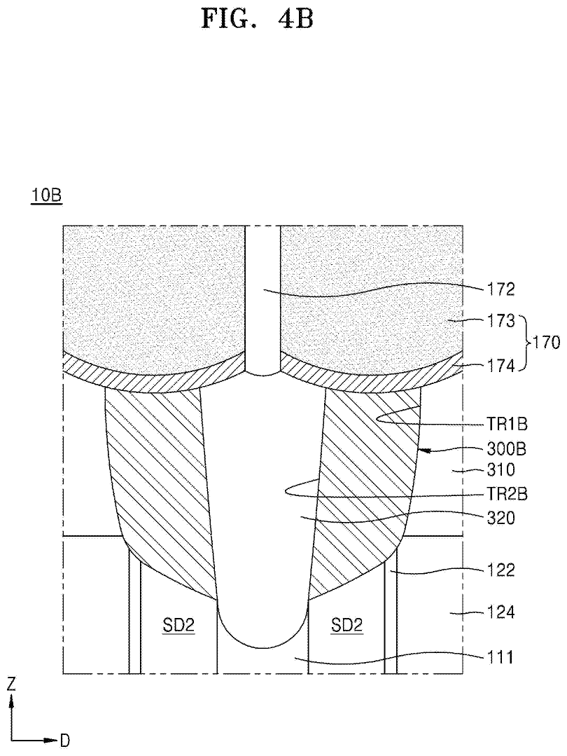

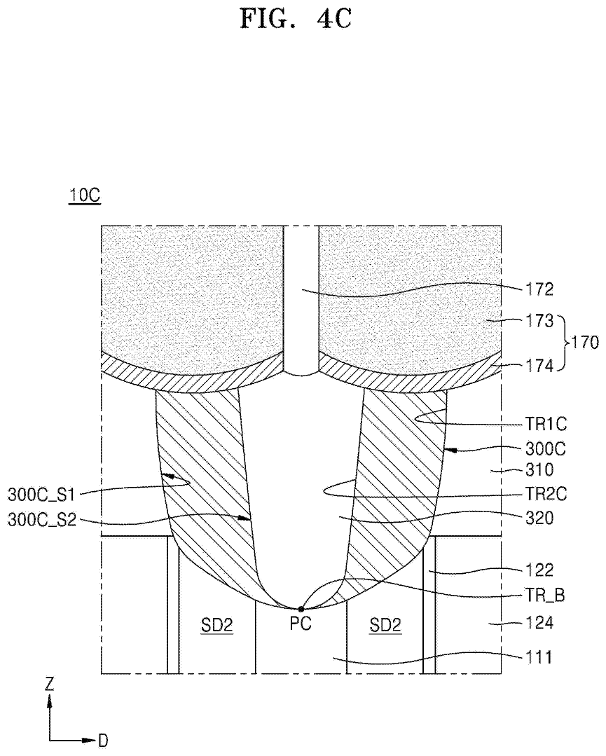

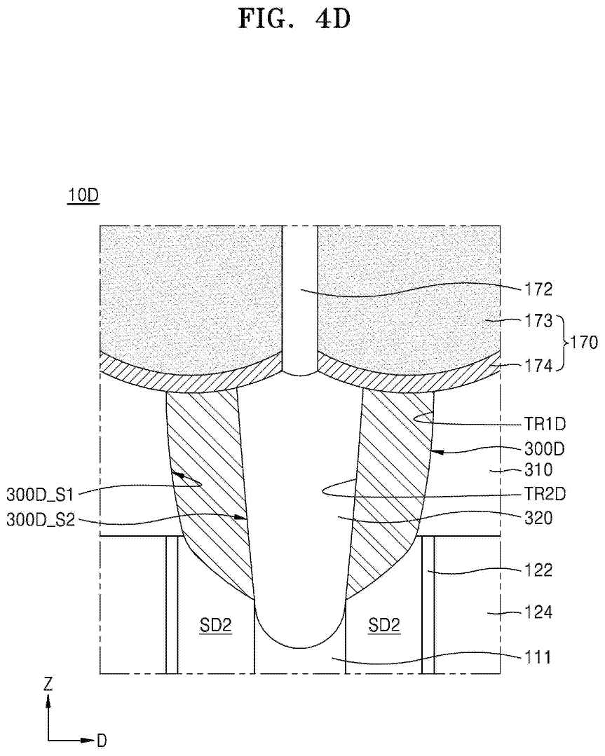

FIGS. 4A to 4D are enlarged cross-sectional views illustrating some components of semiconductor devices 10A, 10B, 10C, and 10D according to example embodiments. Specifically, FIGS. 4A to 4D are enlarged cross-sectional views corresponding to the EX1 region of FIG. 2A. Hereinafter, differences will be mainly described in comparison with FIG. 3.

Referring to FIG. 4A, the semiconductor device 10A may include a plurality of additional pads 300A disposed in a first trench TR1A. Specifically, the plurality of additional pads 300A may be disposed between the first trench TR1A and a second trench TR2A penetrating a lower surface of the first trench TR1A. That is, the plurality of additional pads 300A may be disposed within the first trench TR1A and outside the second trench TR2A.

In some embodiments, the additional pad 300A may include a first surface 300A_S1 and a second surface 300A_S2. The first surface 300A_S1 of the additional pad 300A may overlap the word line 120 (see FIG. 2A) in the vertical direction (e.g., Z direction), and the second surface 300A_S2 may not overlap the word line 120 in the vertical direction (e.g., Z direction). The first surface 300A_S1 and the second surface 300A_S2 of the additional pad 300A may meet with a cusp PA.

In some embodiments, in terms of cross-sectional area, the first surface 300A_S1 may include a first-first surface 300A_S11 having a constant slope and a first-second surface 300A_S12 having a varying slope. For example, the first-first surface 300A_S11 may be perpendicular to the upper surface of the substrate 110 (see FIG. 2A). For example, the first-first surface 300A_S11 may not be perpendicular to the upper surface of the substrate 110.

In some embodiments, in terms of cross-sectional area, the second surface 300A_S2 may include a second-first surface 300A_S21 having a constant slope and a second-second surface 300A_S22 having a varying slope. For example, the second-first surface 300A_S21 may be perpendicular to the upper surface of the substrate 110. For example, the second-first surface 300A_S21 may not be perpendicular to the upper surface of the substrate 110.

Referring to FIG. 4B, the semiconductor device 10B may include a plurality of additional pads 300B disposed in a first trench TR1B. Specifically, the plurality of additional pads 300B may be disposed between the first trench TR1B and a second trench TR2B penetrating a lower surface of the first trench TR1B. That is, the plurality of additional pads 300B may be disposed within the first trench TR1B and outside the second trench TR2B.

In some embodiments, the first trench TR1B in which the additional pad 300B is disposed may expose the second impurity region SD2 and may simultaneously expose the gate dielectric film 122 and the dummy buried insulating film 124. That is, the additional pad 300B disposed in the first trench TR1B may be connected to the second impurity region SD2 and may also contact the gate dielectric film 122 and the dummy buried insulating film 124.

Referring to FIG. 4C, the semiconductor device 10C may include a plurality of additional pads 300C disposed in a first trench TR1C. Specifically, the plurality of additional pads 300C may be disposed between the first trench TR1C and a second trench TR2C on a lower surface of the first trench TR1C. That is, the plurality of additional pads 300C may be disposed within the first trench TR1C and outside the second trench TR2C.

In some embodiments, a width of the first trench TR1C at a vertical level may be greater than that of the second trench TR2C at the same vertical level. On the other hand, unlike the semiconductor device 10 described with reference to FIG. 3, a depth of the second trench TR2C of the semiconductor device 10C may be the same as that of the first trench TR1C. That is, the second trench TR2C may be disposed on a lower surface of the first trench TR1C without penetrating the lower surface of the first trench TR1C. For example, the second trench TR2C may contact the first trench TR1C on the lower surface of the first trench TR1C.

In some embodiments, the additional pad 300C may include a first surface 300C_S1 overlapping the word line 120 (see FIG. 2A) in the vertical direction (e.g., Z direction) and a second surface 300C_S2 that does not overlap the word line 120 in the vertical direction (e.g., Z direction). The first surface 300C_S1 of the additional pad 300C may be disposed on an inner wall of the first trench TR1C, and the second surface 300C_S2 may be disposed on an outer wall of the second trench TR2C. In terms of cross-sectional area, the first surface 300C_S1 and the second surface 300C_S2 may meet with a cusp PC. For example, the first trench TR1C and the second trench TR2C may contact each other at the cusp PC. In some embodiments, the cusp PC may be a point having a lowest vertical level on lower surfaces of each of the first trench TR1C and the second trench TR2C. Unlike shown, the first trench TR1C and the second trench TR2C may be misaligned, and the cusp PC may not be a point at which the lower surface of each of the first trench TR1C and/or the second trench TR2C has the lowest vertical level.

Referring to FIG. 4D, the semiconductor device 10D may include a plurality of additional pads 300D disposed in a first trench TR1D. Specifically, the plurality of additional pads 300D may be disposed between the first trench TR1D and a second trench TR2D penetrating a lower surface of the first trench TR1D. That is, the plurality of additional pads 300D may be disposed within the first trench TR1D and outside the second trench TR2D.

In some embodiments, the first trench TR1D in which the additional pad 300D is disposed may expose the second impurity region SD2, while the gate dielectric film 122 may not be exposed. That is, while the additional pad 300D disposed in the first trench TR1D may be connected to the second impurity region SD2, the additional pad 300D may not contact the gate dielectric film 122.

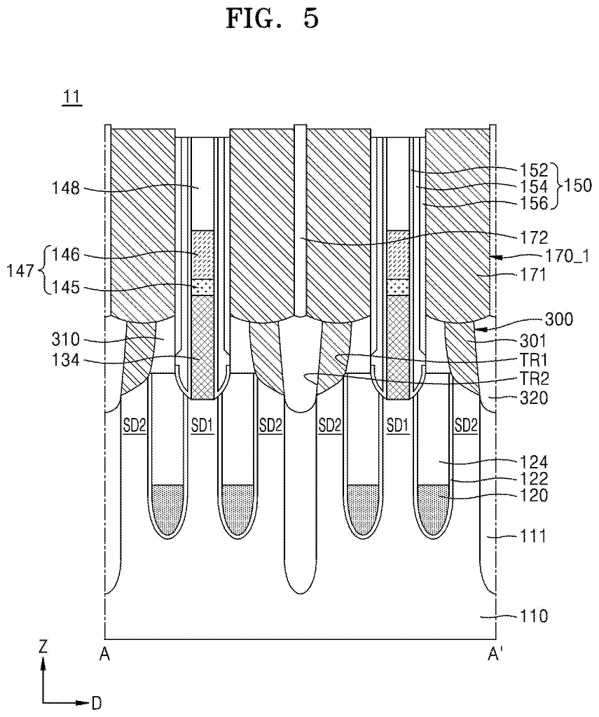

FIG. 5 is a cross-sectional view showing some components of a semiconductor device 11 according to example embodiments. Hereinafter, differences from the semiconductor device 10 described with reference to FIG. 2A will be mainly described.

Referring to FIG. 5, the semiconductor device 11 may include an additional pad 300 including a first polysilicon layer 301 and a buried contact 170_1 disposed on the additional pad 300. The buried contact 170_1 may be electrically connected to the second impurity region SD2 through the additional pad 300. In some embodiments, the buried contact 170_1 may include a second polysilicon layer 171. The second polysilicon layer 171 may be disposed on the first polysilicon layer 301. For example, the first polysilicon layer 301 and the second polysilicon layer 171 may contact each other.

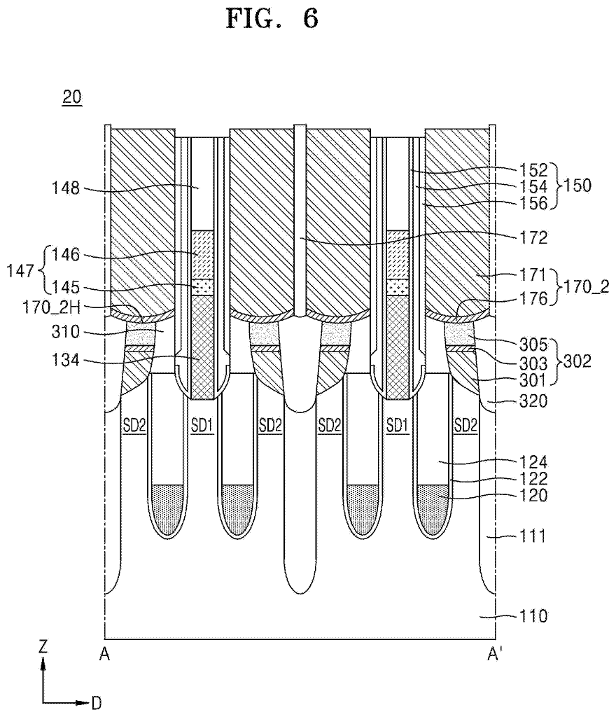

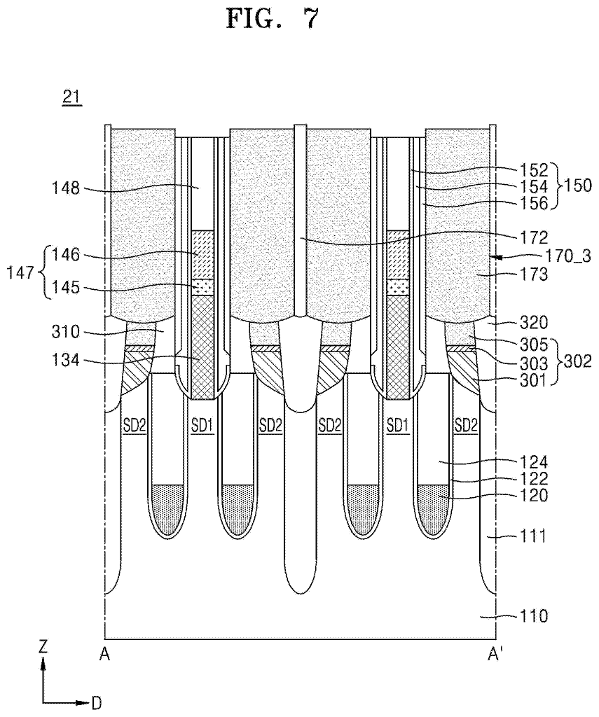

FIGS. 6 and 7 are cross-sectional views illustrating some components of semiconductor devices 20 and 21 according to example embodiments. Hereinafter, differences from the semiconductor device 10 described with reference to FIG. 2A will be mainly described.

Referring to FIG. 6, the semiconductor device 20 may include an additional pad 302 including a first polysilicon layer 301 and a buried contact 170_2 disposed on the additional pad 302. The buried contact 170_2 may be electrically connected to the second impurity region SD2 through the additional pad 302.

In some embodiments, the additional pad 302 may further include a second silicide film 303 on the first polysilicon layer 301, and a second metal conductive layer 305 on the second silicide film 303. Specifically, the second metal conductive layer 305 may be spaced apart from the first polysilicon layer 301 with the second silicide film 303 therebetween.

In some embodiments, the buried contact 170_2 may include a third silicide film 176 and a second polysilicon layer 171 disposed in a buried contact hole 170_2H. In some embodiment, the third silicide film 176 may be disposed on a lower surface of the buried contact hole 170_2H. The second polysilicon layer 171 may be disposed on the third silicide film 176. The second polysilicon layer 171 may be spaced apart from the second metal conductive layer 305 with the third silicide film 176 therebetween.

Referring to FIG. 7, the semiconductor device 21 may include an additional pad 302 including a first polysilicon layer 301 and a buried contact 170_3 disposed on the additional pad 302. The buried contact 170_3 may be electrically connected to the second impurity region SD2 through the additional pad 302.

In some embodiments, the additional pad 302 may further include a second silicide film 303 on the first polysilicon layer 301, and a second metal conductive layer 305 on the second silicide film 303. Specifically, the second metal conductive layer 305 may be spaced apart from the first polysilicon layer 301 with the second silicide film 303 therebetween.

In some embodiments, the buried contact 170_3 may include a first metal conductive layer 173. Unlike the buried contact 170 of the semiconductor device 10 described with reference to FIG. 2A, the buried contact 170_3 may not include the first silicide film 174 (see FIG. 2A). The first metal conductive layer 173 may be disposed on the second metal conductive layer 305. For example, the first metal conductive layer 173 and the second metal conductive layer 305 may contact each other.

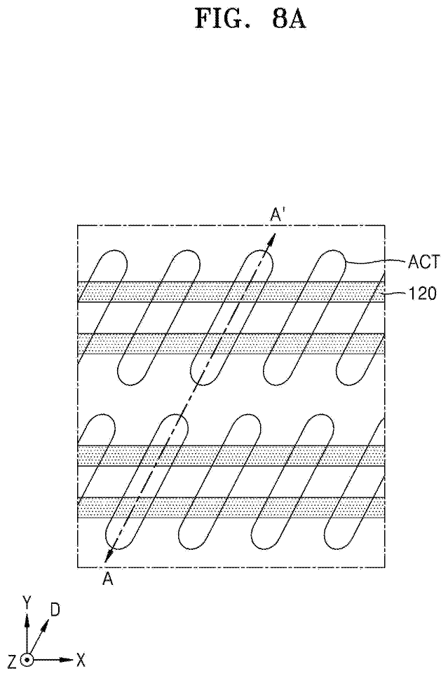

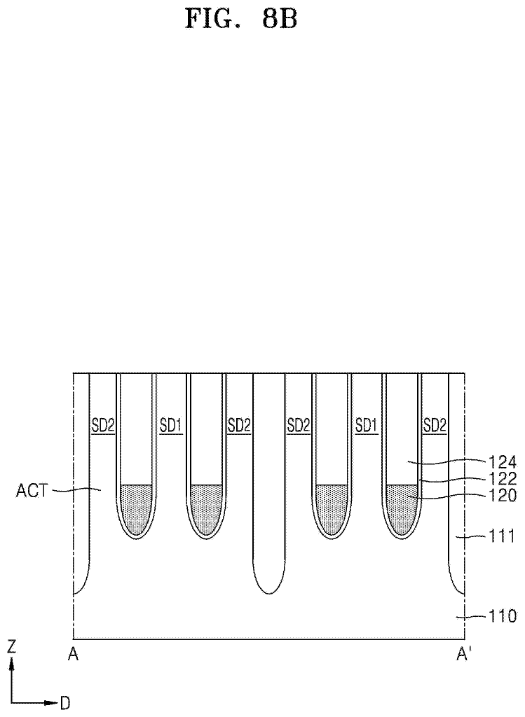

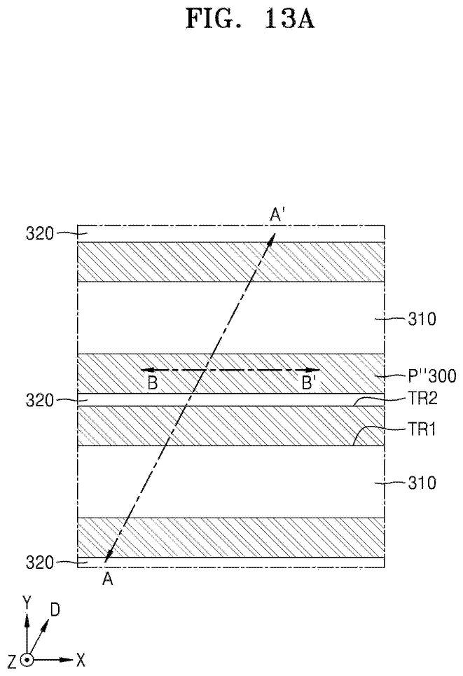

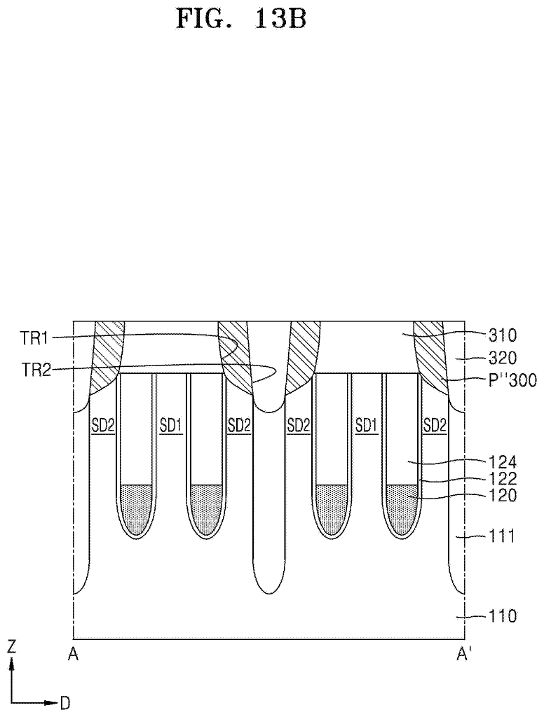

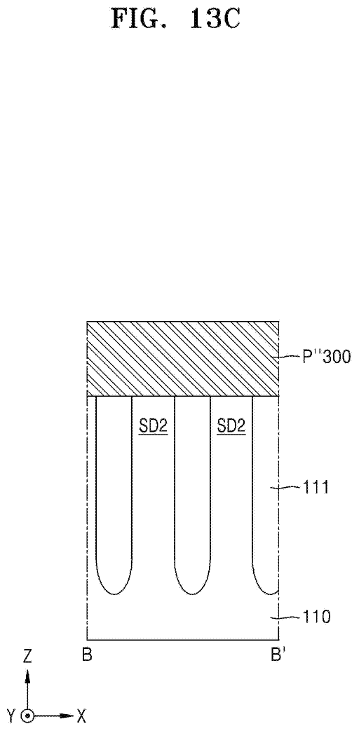

FIGS. 8A, 8B, 9A, 9B, 10A, 10B, 11A, 11B, 12A, 12B, 13A, 13B, 13C, 14A, 14B, FIGS. 15A, 15B, and 15C are diagrams for explaining a method of manufacturing a semiconductor device, according to example embodiments. Specifically, FIGS. 8A, 9A, 10A, 11A, 12A, 13A, 14A, and 15A are plan views for explaining a method of manufacturing a semiconductor device, according to embodiments. Specifically, FIGS. 8B, 9B, 10B, 11B, 12B, 13B, and 15B are cross-sectional views taken along lines A-A′ of FIGS. 8A, 9A, 10A, 11A, 12A, 13A, and 15A, respectively. Specifically, FIGS. 13C, 14B, and 15C are cross-sectional views taken along lines B-B′ of FIGS. 13A, 14A, and 15A, respectively.

Referring to FIGS. 8A and 8B, a plurality of active regions ACT defined by an element isolation film 111 and a plurality of word lines 120 crossing the plurality of active regions ACT in the first horizontal direction (e.g., X direction) may be disposed in a substrate 110. The word line WL may separate the active region ACT into a first impurity region SD1 and a second impurity region SD2. The first impurity region SD1 and the second impurity region SD2 may be spaced apart with the word line WL therebetween.

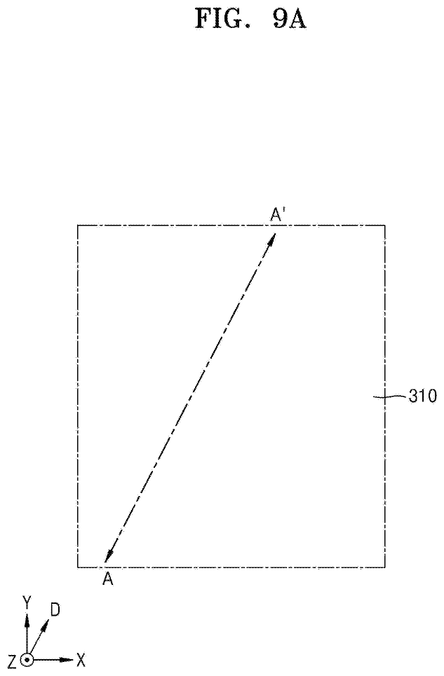

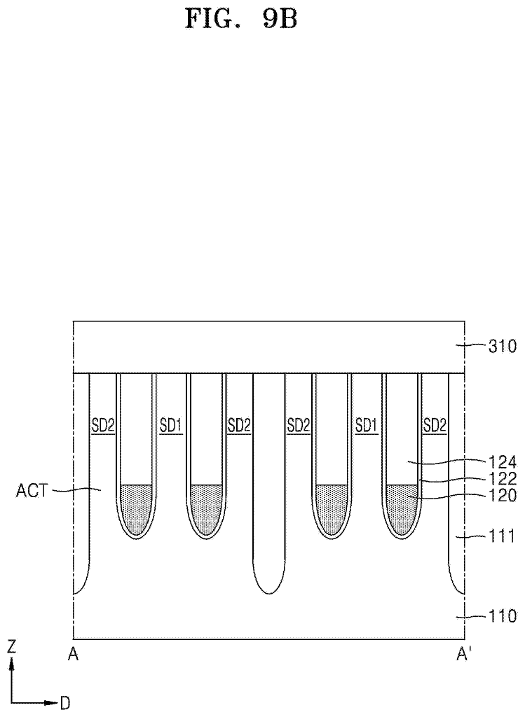

Referring to FIGS. 9A and 9B, an interlayer insulating film 310 may be formed on the substrate 110. The interlayer insulating film 310 may be disposed on (e.g., may cover) the element isolation film 111 and the plurality of active regions ACT. The interlayer insulating film 310 may include, for example, silicon nitride, silicon oxide, and/or silicon oxynitride.

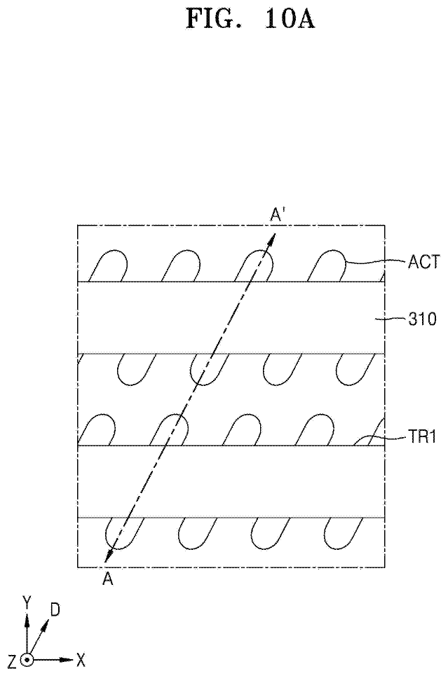

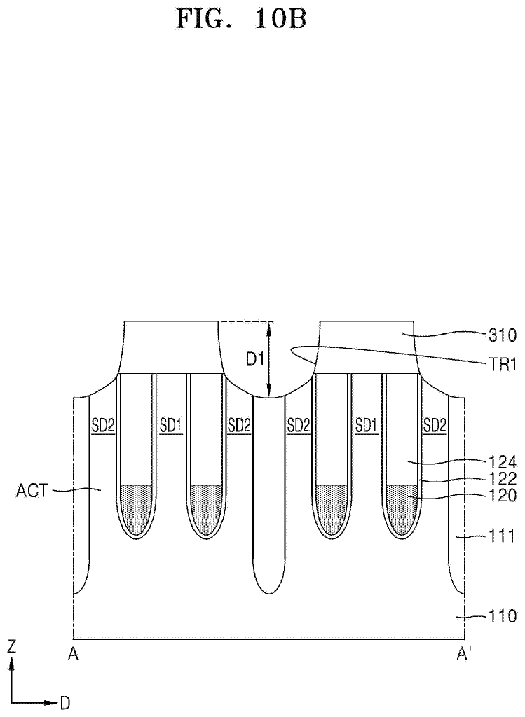

Referring to FIGS. 10A and 10B, a first trench TR1 penetrating the interlayer insulating film 310 and extending in the first horizontal direction (e.g., X direction) may be formed. The first trench TR1 may expose portions of each of the plurality of active regions ACT. For example, the first trench TR1 may expose an edge portion of each of the plurality of active regions ACT. The first trench TR1 may be formed by penetrating the interlayer insulating film 310 on top (e.g., upper portion) of the element isolation film 111 disposed between the second impurity region SD2 and two adjacent active regions ACT, and recessing a portion of the element isolation film 111 disposed between the second impurity region SD2 and two adjacent active regions ACT. That is, the first trench TR1 may expose the second impurity region SD2 and the element isolation film 111 disposed between two adjacent active regions ACT. For example, a pair of second impurity regions SD2 exposed by one first trench TR1 may be a second impurity region SD2 adjacent to a different active region ACT among second impurity regions SD2 of each of the two adjacent active regions ACT.

In some embodiments, the first trench TR1 may have a first depth D1. The first depth D1 may be a distance from a vertical level of an upper surface of the interlayer insulating film 310 to the lowest vertical level of the first trench TR1.

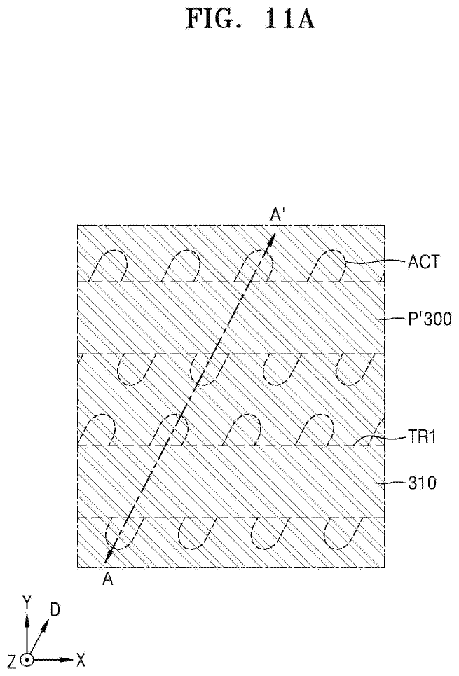

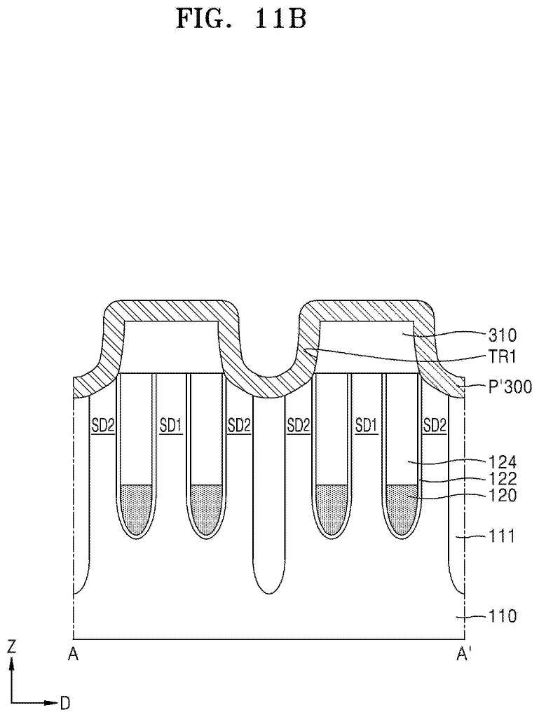

Referring to FIGS. 11A and 11B, a first pre-polysilicon layer P′300 may be formed on the substrate 110. Specifically, the first pre-polysilicon layer P′300 may be formed to conformally cover the inner wall of the first trench TR1 and the upper surface of the interlayer insulating film 310. For example, the first pre-polysilicon layer P′300 may be formed on the interlayer insulating film 310, the second impurity region SD2, and the element isolation film 111. That is, the first pre-polysilicon layer P′300 may be formed on the second impurity region SD2 exposed by the first trench TR1. That is, the first pre-polysilicon layer P′300 may contact the second impurity region SD2 exposed by the first trench TR1.

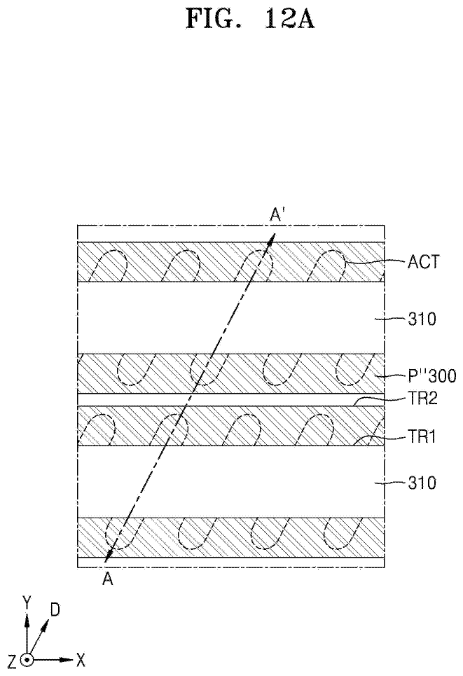

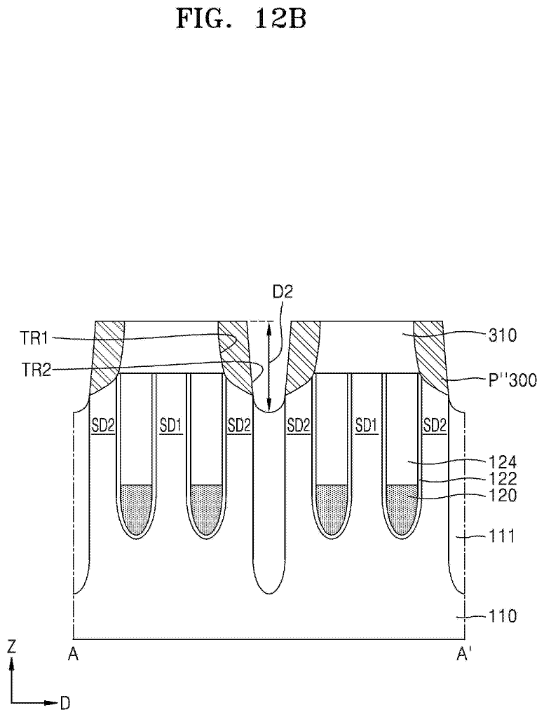

Referring to FIGS. 12A and 12B, a portion of the first pre-polysilicon layer P′300 (see FIGS. 11A and 11B) may be etched. Specifically, a portion of the first pre-polysilicon layer P′300 on the upper surface of the interlayer insulating film 310 and a portion of the first pre-polysilicon layer P′300 inside the first trench TR1 may be etched. The etching process may include an anisotropic etching process. Specifically, in the etching process, a portion of the first pre-polysilicon layer P′300 may be etched in the vertical direction (e.g., Z direction). For example, a portion of the first pre-polysilicon layer P′300 disposed on the inner wall of the first trench TR1 that is not exposed in the vertical direction (e.g., Z direction) may not be etched or may be substantially less etched compared to the inner wall of the first trench TR1 that is exposed in the vertical direction (e.g., Z direction). The first pre-polysilicon layer P′300 may be etched to form a second pre-polysilicon layer P″300.

In some embodiments, a second trench TR2 penetrating the lower surface of the first trench TR1 and extending in the first horizontal direction (e.g., X direction) may be formed by the etching process. The second trench TR2 may be formed by penetrating the first pre-polysilicon layer P′300 and the lower surface of the first trench TR1, and recessing a portion of the element isolation film 111 under the first trench TR1.

In some embodiments, the second trench TR2 may have a second depth D2. The second depth D2 may be a distance from a vertical level of an upper surface of the interlayer insulating film 310 to the lowest vertical level of the second trench TR2. The second depth D2 of the second trench TR2 may be greater than the first depth D1 of the first trench TR1 (see FIG. 10B). The second trench TR2 may have a smaller width than the first trench TR1 at the same vertical level. Specifically, the width of the second trench TR2 in the second horizontal direction (e.g., Y direction) may be less than the width of the first trench TR1 in the second horizontal direction (e.g., Y direction).

In some embodiments, the second pre-polysilicon layer P″300 may be disposed in a space formed by the first trench TR1 and the second trench TR2. The second pre-polysilicon layer P″300 may extend in the first horizontal direction (e.g., X direction). A pair of second pre-polysilicon layers P″300 disposed in the first trench TR1 may be separated from each other by the second trench TR2. The second pre-polysilicon layer P″300 may be disposed on the second impurity region SD2 and may contact the second impurity region SD2.

Referring to FIGS. 13A to 13C, an inter-pad insulating film 320 may be disposed in (e.g., may fill) the second trench TR2. The inter-pad insulating film 320 may include, for example, silicon nitride, silicon oxide, and/or silicon oxynitride. The inter-pad insulating film 320 may extend in the first horizontal direction (e.g., X direction) and may be disposed between a pair of second pre-poly-silicon layers P″300 disposed in the first trench TR1 adjacent to (e.g., by) the second trench TR2.

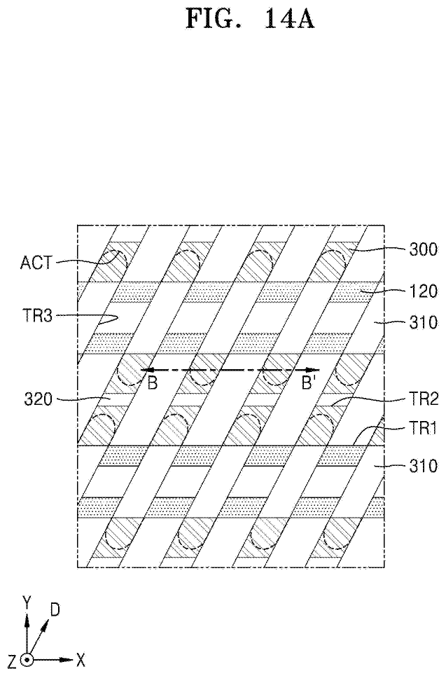

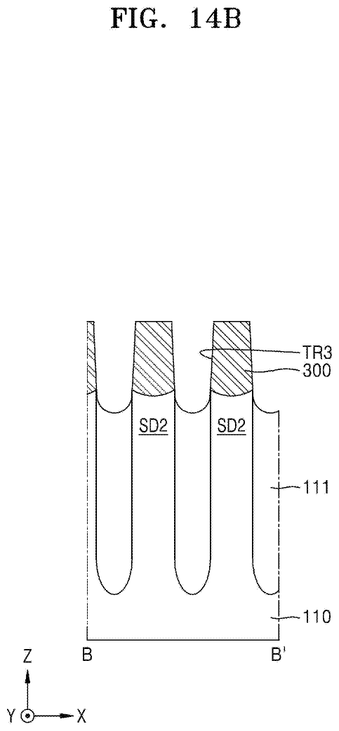

Referring to FIGS. 14A and 14B, a third trench TR3 extending in the oblique direction (e.g., D direction) may be formed. That is, the additional pad 300 may be defined by the first trench TR1, the second trench TR2, and the third trench TR3. Specifically, the additional pad 300 may be defined by the inner wall of the first trench TR1, the outer wall of the second trench TR2, and the outer wall of the third trench TR3.

In some embodiments, the third trench TR3 may separate the second pre-polysilicon layer P″300 into a plurality of additional pads 300 arranged in the first horizontal direction (e.g., X direction). In some embodiments, the third trench TR3 may expose portions of the plurality of word lines 120. The third trench TR3 may be formed by recessing an upper portion of the element isolation film 111.

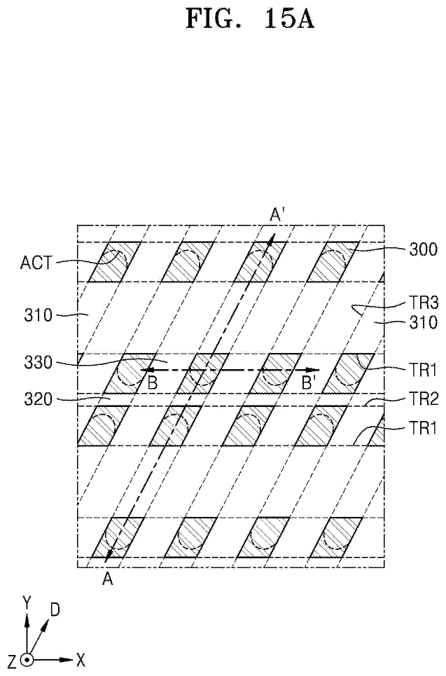

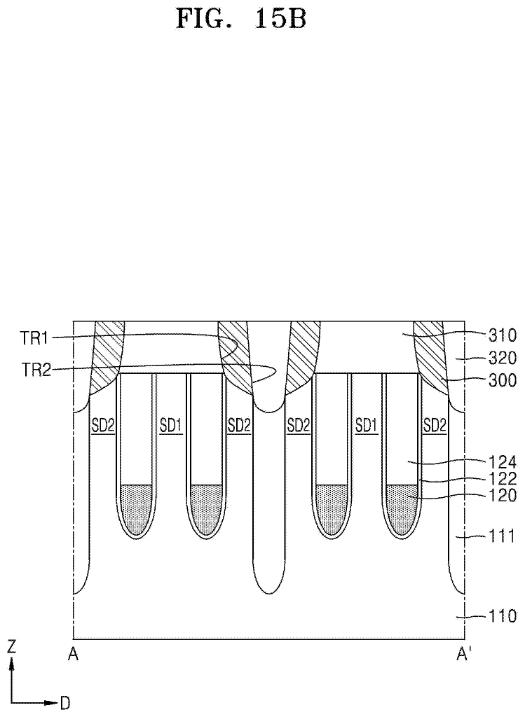

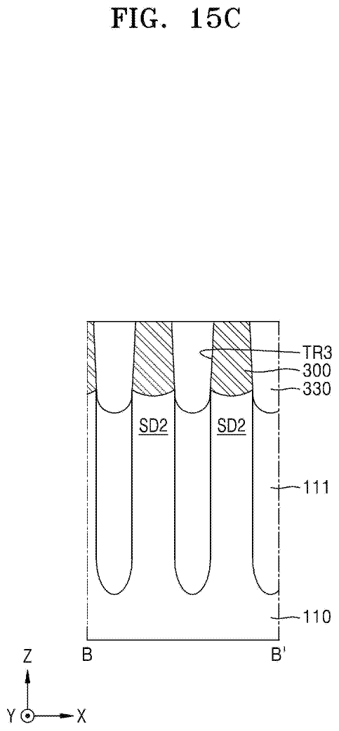

Referring to FIGS. 15A to 15C, an inter-pad insulating film 330 may be disposed in (e.g., may fill) the third trench TR3. The inter-pad insulating film 330 may be disposed between the plurality of additional pads 300 adjacent to each other in the first horizontal direction (e.g., X direction).

According to the method of manufacturing a semiconductor device according to some embodiments of the inventive concept described with reference to FIGS. 8A to 15C, a semiconductor device including the additional pads 300 arranged at different intervals from adjacent additional pads 300 may be manufactured. Specifically, the additional pad 300 may include a pair of first additional pad 300_1 and second additional pad 300_2 adjacent in the oblique direction (e.g., D direction) within the first trench TR1, and by forming the first trench TR1, a site for the first additional pad 300_1 and a site for the second additional pad 300_2 may be simultaneously formed. Accordingly, a semiconductor device having improved performance and reliability may be provided by the method of manufacturing a semiconductor device according to embodiments.

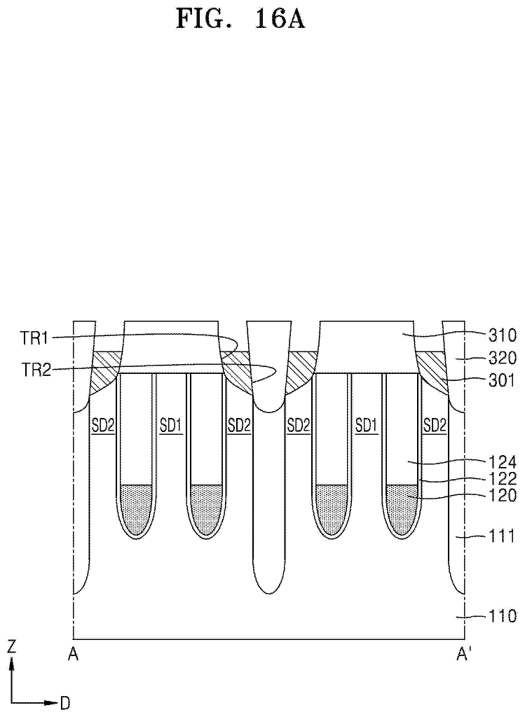

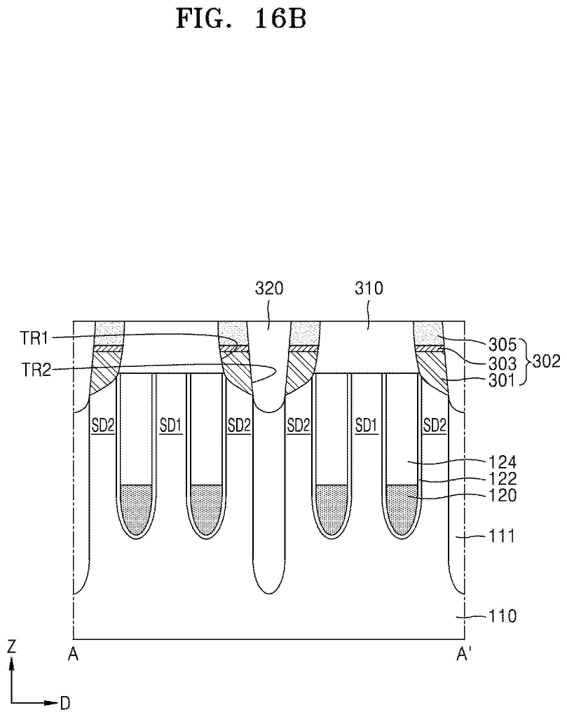

FIGS. 16A and 16B are cross-sectional views illustrating a method of manufacturing a semiconductor device, according to example embodiments. Specifically, FIGS. 16A and 16B are cross-sectional views corresponding to the cross-section taken along line A-A′ of FIG. 1A, and are cross-sectional views for explaining a method of manufacturing a semiconductor device performed subsequent to FIG. 15B.

Referring to FIG. 16A, an upper portion of the first polysilicon layer 301 of the additional pad 300 may be etched back. For example, the top (e.g., upper portion) of the first polysilicon layer 301 of the additional pad 300 may be removed. That is, the upper surface of the first polysilicon layer 301 may be at a lower vertical level than the upper surface of the interlayer insulating film 310.

Referring to FIG. 16B, a second silicide film 303 and a second metal conductive layer 305 may be formed on the first polysilicon layer 301. The second metal conductive layer 305 may be spaced apart from the first polysilicon layer 301 with the second silicide film 303 therebetween. An upper surface of the second metal conductive layer 305 may be at the same vertical level as an upper surface of the interlayer insulating film 310. However, in a subsequent process, upper portions of the second metal conductive layer 305 and the interlayer insulating film 310 may be recessed and positioned at different vertical levels. As a result, an additional pad 302 including the first polysilicon layer 301, the second silicide film 303, and the second metal conductive layer 305 may be formed.

In some other embodiments, before the formation of the third trench TR3, forming the second silicide film 303 and the second metal conductive layer 305 described with reference to FIGS. 16A and 16B may be performed. That is, after removing the upper part of the second pre-polysilicon layer P″300 by etching back the upper part of the second pre-polysilicon layer P″300, forming the second silicide film 303 and the second metal conductive layer 305 on the second pre-polysilicon layer P″300 may be performed. Thereafter, the additional pad 300 may be manufactured by forming the third trench TR3.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” “higher” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

In one example, when a certain embodiment may be implemented differently, processes or methods may occur in a sequence different from that specified in the description herein. For example, two consecutive processes may actually be executed at the same time. Depending on a related function or operation, the processes may be executed in a reverse sequence. Moreover, a process may be separated into multiple processes and/or may be at least partially integrated.

In descriptions of temporal relationships, for example, temporal precedent relationships between two events such as “after”, “subsequent to”, “before”, etc., another event may occur therebetween unless “directly after”, “directly subsequent” or “directly before” is not indicated.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

While the inventive concept has been particularly shown and described with reference to embodiments thereof, it will be understood that various changes in form and details may be made therein without departing from the spirit and scope of the following claims.

What is claimed is:

1. A semiconductor device comprising:
an active region defined by an element isolation film in a substrate;
a word line extending in a first horizontal direction in the substrate;
a bit line extending in a second horizontal direction crossing the first horizontal direction on the substrate;
an additional pad disposed on the active region; and
a buried contact on the additional pad
wherein the buried contact is electrically connected to the active region by the additional pad,
wherein the additional pad comprises a first surface that overlaps the word line in a vertical direction, and a second surface that is free of overlap with the word line in the vertical direction, and
wherein, the first surface meets the second surface at a cusp.

2. The semiconductor device of claim 1, wherein the additional pad comprises a polysilicon layer.

3. The semiconductor device of claim 2, wherein the additional pad further comprises a silicide film on the polysilicon layer and a metal conductive layer on the silicide film.

4. The semiconductor device of claim 1, wherein the cusp is free of overlap with an upper surface of the additional pad in the vertical direction.

5. The semiconductor device of claim 4, wherein the cusp is free of overlap with the word line in the vertical direction.

6. The semiconductor device of claim 1, wherein the active region comprises a first impurity region and second impurity regions spaced apart from each other with the first impurity region therebetween,
wherein the semiconductor device further comprises a direct contact electrically connecting the bit line to the first impurity region, and
wherein the buried contact is electrically connected to the second impurity region by the additional pad.

7. A semiconductor device comprising:
a substrate;
a plurality of active regions extending in an oblique direction in the substrate;
a plurality of word lines crossing the plurality of active regions in a first horizontal direction and separating each of the plurality of active regions into a first impurity region and a second impurity region;
a plurality of bit lines extending in a second horizontal direction crossing the first horizontal direction on the substrate;
a plurality of direct contacts electrically connecting the plurality of bit lines to the first impurity regions, respectively;
a first trench extending in the first horizontal direction and exposing the second impurity regions of two adjacent active regions among the plurality of active regions;
a second trench passing through a lower surface of the first trench in the first trench;
a plurality of additional pads between the first trench and the second trench; and
a plurality of buried contacts electrically connected to the second impurity regions by the plurality of additional pads,
wherein the plurality of direct contacts is arranged in the first horizontal direction, and
wherein lower surfaces of the first trench and lower surfaces of the second trench are concave with respect to an upper surface of the substrate.

8. The semiconductor device of claim 7, wherein the plurality of additional pads is disposed on an inner wall of the first trench and an outer wall of the second trench.

9. The semiconductor device of claim 7, wherein a depth of the first trench is less than a depth of the second trench, relative to the substrate.

10. The semiconductor device of claim 7, wherein a width of the first trench is at least equal to or greater than a width of the second trench at a same vertical level, relative to the substrate.

11. The semiconductor device of claim 7, wherein a pair of additional pads among the plurality of additional pads adjacent to each other in the oblique direction within the first trench are separated by the second trench.

12. The semiconductor device of claim 7, wherein the plurality of additional pads comprises a first polysilicon layer.

13. The semiconductor device of claim 12, wherein the plurality of buried contacts comprises a first metal conductive layer, and
wherein the first metal conductive layer is spaced apart from the first polysilicon layer with a first silicide film therebetween.

14. The semiconductor device of claim 12, wherein the plurality of additional pads further comprises a second silicide film on the first polysilicon layer and a second metal conductive layer spaced apart from the first polysilicon layer with the second silicide film therebetween.

15. The semiconductor device of claim 14, wherein the plurality of buried contacts includes a second polysilicon layer, and
wherein the second polysilicon layer is spaced apart from the second metal conductive layer with a third silicide film therebetween.

16. The semiconductor device of claim 12, wherein the plurality of buried contacts comprises a second polysilicon layer.

17. A semiconductor device comprising:
a substrate;
a plurality of active regions extending in an oblique direction in the substrate and spaced apart from each other in a first horizontal direction;
a plurality of word lines crossing the plurality of active regions in the first horizontal direction and separating each of the plurality of active regions into a first impurity region and second impurity regions spaced apart from each other with the first impurity region therebetween;
a plurality of bit lines extending in a second horizontal direction crossing the first horizontal direction on the substrate and electrically connected to the first impurity regions by a plurality of direct contacts, respectively;
a first trench extending in the first horizontal direction and exposing the second impurity regions of two adjacent active regions among the plurality of active regions;
a second trench extending in the first horizontal direction, having a width equal to or narrower than that of the first trench in the second horizontal direction at a same vertical level, relative to the substrate, and passing through a lower surface of the first trench;
a plurality of additional pads disposed inside the first trench and outside the second trench, the plurality of additional pads, respectively including a first polysilicon layer; and
a plurality of buried contacts electrically connected to the second impurity regions by the plurality of additional pads, respectively,
wherein each of the plurality of additional pads comprises a first surface that overlaps one of the plurality of word lines in a vertical direction, and a second surface that is free of overlap with the plurality of word lines in the vertical direction, and
wherein the first surface meets the second surface at a cusp.

18. The semiconductor device of claim 17, wherein the plurality of additional pads, respectively comprises a second metal conductive layer disposed on the first polysilicon layer.

19. The semiconductor device of claim 17, wherein the plurality of buried contacts, respectively comprises one selected from a second polysilicon layer and a first metal conductive layer.

20. The semiconductor device of claim 17, wherein a pair of additional pads among the plurality of additional pads adjacent in the oblique direction within the first trench are separated by the second trench.
